(19) United States
(12) Patent Application Publication
(10) Pub. No.: US 2016/0032455 A1
(43) Pub. Date: Feb. 4, 2016

(54) HIGH THROUGH-PUT AND LOW TEMPERATURE ALD COPPER DEPOSITION AND INTEGRATION

(71) Applicant: Applied Materials, Inc., Santa Clara, CA (US)

(72) Inventors: Feng Q. Liu, San Jose, CA (US); Ben-Li Sheu, Sunnyvale, CA (US); David Thompson, San Jose, CA (US); Mei Chang, Saratoga, CA (US); Paul F. Ma, Santa Clara, CA (US); David Knapp, Santa Clara, CA (US); Jeffrey W. Anthis, San Jose, CA (US); Annamalai Lakshmanan, Fremont, CA (US)

(21) Appl. No.: 14/815,625

(22) Filed: Jul. 31, 2015

Related U.S. Application Data
(60) Provisional application No. 62/031,612, filed on Jul. 31, 2014.
(60) Provisional application No. 62/195,753, filed on Jul. 22, 2015.

(51) Int. Cl. C23C 16/455; C25D 3/38; C25D 5/34; C23C 16/18; C23C 16/02

(52) U.S. Cl. CPC C23C 16/45553; C23C 16/18; C23C 16/0209; C25D 5/34; C25D 3/38

(57) ABSTRACT

Methods of depositing a metal layer utilizing organometallic compounds. A substrate surface is exposed to a gaseous organometallic metal precursor and an organometallic metal reactant to form a metal layer (e.g., a copper layer) on the substrate.

### CROSS-REFERENCE TO RELATED APPLICATIONS

This application claims the benefit under 35 U.S.C. §119(e) to U.S. Provisional Application No. 62/031,612, filed Jul. 31, 2014, and U.S. Provisional Application No. 62/195,753, filed Jul. 22, 2015, the entire contents of which is incorporated herein by reference in their entirety.

### TECHNICAL FIELD

Principles and embodiments of the present disclosure generally relate to the deposition of metal layers by atomic layer deposition (ALD) conducted at low temperatures.

### BACKGROUND

As feature size and critical dimensions of integrated circuit components go below 20 nm, the challenge of forming interconnect lines by copper (Cu) integration, and the formation of barrier layers and Cu seed layers becomes more and more difficult.

Chemical vapor deposition has been used to produce metallic interconnects on substrates containing microelectronic circuits. However, CVD typically is carried out at temperatures in the range of 300° C. to 600° C.

Chemical vapor deposition (CVD) processes have proven to be unable to deposit a continuous metal layer over the smaller feature sizes, at least partially due to higher temperatures needed to initiate CVD reactions. The higher temperatures increase atomic and molecular mobility on substrate surfaces, which has been shown to lead to agglomeration of metal atoms into distinct islands that can leave portions of a feature uncoated. Processes that result in such islands can then require thicker layers to ensure continuous coverage of a surface feature. As the feature size and critical dimensions of integrated circuit components go below 20 nm, however, there is insufficient room for the addition of more material.

Physical vapor deposition (PVD) is a non-selective, anisotropic deposition process that has directional (e.g., line-of-sight) characteristics. The directional characteristics can result in shadowing and uneven coating thicknesses (e.g., poor step coverage, overhangs, greater thickness at the center of trenches, etc.) that result in discontinuous layers on the small feature sizes. Vertical and high aspect ratio features tend to be less or even uncoated because the metal vapor deposition atoms move in a direction that is essentially parallel with the vertical features.

Atomic layer deposition (ALD) methods involve sequential surface reactions, where precursors saturate the exposed surface, and which result in the formation of a monolayer in each sequence. ALD, therefore, is generally a self-limiting growth process that produces uniform thin films. Because ALD is self-limiting and involves gas phase precursors that can enter trenches and vias, the method can be used to form uniform thin films on high aspect ratio surfaces.

There is an ongoing need in the art for materials, methods, and processes, to provide continuous and conformal Cu seed layers at smaller feature sizes.

### SUMMARY

An aspect of the present disclosure relates generally to a method comprising heating a substrate to a temperature in the range of about 60° C. to about 150° C., exposing the surface of the substrate to a gaseous organometallic metal precursor to form a film of the organometallic metal precursor on the surface of the substrate, exposing the surface of the substrate and the film of the organometallic metal precursor to a gaseous organometallic metal reactant that reacts with the organometallic metal precursor on the surface to form a metal layer on the substrate.

Another aspect of the present disclosure relates generally to a method comprising placing a substrate within a reaction chamber, heating the substrate to an intended temperature, introducing a gaseous organometallic metal precursor into the reaction chamber, wherein at least a portion of the substrate surface is exposed to the gaseous organometallic metal precursor, adsorbing the organometallic metal precursor onto the substrate surface, wherein the adsorbed organometallic metal precursor forms a continuous and conformal film on the substrate surface, introducing a gaseous organometallic metal reactant into the reaction chamber, wherein at least a portion of the continuous and conformal film on the substrate surface is exposed to the gaseous organometallic metal reactant, and reacting the organometallic metal precursor with the organometallic metal reactant at the intended temperature to deposit a metal layer on the substrate surface.

Another aspect of the present disclosure relates generally to a method comprising placing a substrate having a substrate surface within a reaction chamber, heating the substrate to a temperature in the range of about 75° C. to about 99° C., introducing gaseous Cu(DMAP)₂ into the reaction chamber, wherein at least a portion of the substrate surface is exposed to the gaseous Cu(DMAP)₂, adsorbing the Cu(DMAP)₂ onto the substrate surface, wherein the adsorbed Cu(DMAP)₂ forms a continuous and conformal Cu(DMAP)₂ film on the substrate surface, introducing gaseous trimethyl aluminum or triethyl aluminum into the reaction chamber, wherein at least a portion of the continuous and conformal Cu(DMAP)₂ film on the substrate surface is exposed to the gaseous trimethyl aluminum or triethyl aluminum, and reacting the Cu(DMAP)₂ with trimethyl aluminum or triethyl aluminum to deposit a Cu metal layer on the substrate surface, wherein the Cu metal layer has a thickness of in the range of about 5 Å to about 1,000 Å, and a purity of greater than 99.5%.

### BRIEF DESCRIPTION OF THE DRAWINGS

Further features of embodiment of the present disclosure, their nature and various advantages will become more apparent upon consideration of the following detailed description, taken in conjunction with the accompanying drawings, which are also illustrative of the best mode contemplated by the applicants, and in which like reference characters refer to like parts throughout, where:

FIGS. 1A-1H illustrate an exemplary embodiment of the deposition of material layers;

FIG. 2 illustrates a flowchart for an exemplary embodiment of a conformal metal layer ALD deposition process; and

FIGS. 3A-B illustrates an exemplary embodiment of the deposition of metal layers by ALD and ECD to fill an exemplary surface feature.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

Reference throughout this specification to “one embodiment,” “certain embodiments,” “various embodiments,” “one or more embodiments” or “an embodiment” means that a particular feature, structure, material, or characteristic described in connection with the embodiment may be included in at least one embodiment of the disclosure. Furthermore, the appearances of the phrases such as “in one or more embodiments,” “in certain embodiments,” “in one embodiment” or “in an embodiment” in various places throughout this specification are not necessarily referring to the same embodiment of the disclosure. In addition, the particular features, structures, materials, or characteristics described may be combined in any suitable manner in one or more embodiments.

As used herein, the term “conformal” refers to a layer that adheres to and uniformly covers exposed surfaces with a thickness having a variation of less than 1%. For example, a 1,000 Å thick film would have less than 10 Å variation in thickness. This thickness and variation includes edges, corners, sides, and the bottom of recesses. For example, a conformal layer deposited by ALD in various embodiments of the disclosure would provide coverage over the deposited region of essentially uniform thickness on complex surfaces.

As used herein, the term “continuous” refers to a layer that covers an entire exposed surface without gaps or bare spots that reveal material underlying the deposited layer.

A “substrate surface” as used herein, refers to an exposed face of any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, silicon nitride, silicon carbide, doped silicon, germanium, gallium arsenide, glass, sapphire, and any other materials such as metals, metal nitrides, metal carbides, metal alloys, and other conductive materials, depending on the application. Substrates include, without limitation, semiconductor and insulating wafers, which may or may not have been further processed to produce electronic and/or optoelectronic devices. Substrates may be exposed to a pretreatment process to clean, polish, etch, reduce, oxidize, hydroxylate, anneal and/or bake the substrate surface. In addition to film processing directly on the surface of the substrate itself, in the embodiments of the present disclosure any of the film processing steps disclosed may also be performed on an underlayer formed on the substrate as disclosed in more detail below, and the term “substrate surface” is intended to include such underlayer(s) as the context indicates, for example vias passing through thin semiconducting and/or insulating layers on an SOI wafer.

A problem that arises in using CVD to deposit copper into trenches and vias having small dimensions and high aspect ratios, as those found in present ultra-large-scale integration, is the pinching off of the open space within the narrow high-aspect ratio features. In addition, thin and/or discontinuous coatings may be produced by CVD methods due to the formation of bare portions and islands on various surfaces.

Successful copper integration at sub-20 nm scales involves producing continuous copper seed layers that conform to the walls and steps of the trenches and vias in a substrate.

The embodiments of the present disclosure address the problems of the previous methods by providing a material that can uniformly cover the features on a substrate surface and react at temperatures below those previously employed to produce a continuous and conformal material layer.

According to one or more embodiments, ALD can be used to deposit materials, for example metals, onto or into surface features having less than 3 nm dimensions.

In various embodiments, the method of depositing a metal (e.g., Cu, Ni, Co, Fe) on a substrate may comprise from 20 to 500 ALD deposition cycles, where each cycle comprises depositing a layer of an organometallic metal precursor and a layer of an organometallic metal reactant compound, which can produce a monolayer of deposited metal.

In various embodiments, the thickness of the metal deposited per cycle may be in the range of about 0.4 Å to about 3.0 Å, or in the range of about 0.8 Å to about 2.0 Å, or in the range of about 1.0 Å to about 1.5 Å.

Principles and embodiments of the present disclosure relate to ALD deposition of metal layers at temperatures below those previously utilized.

Embodiments of the present disclosure provide an improved ALD process that provides more conformal coverage of surface features with a deposited metal layer at temperatures less than 150° C., or less than 120° C., or less than 100° C.

In one or more embodiments, a low temperature can be 120° C. or less.

In various embodiments, an organometallic metal precursor and an organometallic metal reactant may form a metal layer at temperatures in the range of about 60° C. to about 119° C., or in the range of about 75° C. to about 99° C., with improved resolution and critical dimension uniformity and control.

An aspect of the present disclosure relates to liquid precursors that provide higher vapor pressures in a reaction chamber than those obtained with solid ALD precursors. In various embodiments, a vapor of the organometallic metal precursor may be generated by heating a liquid or solid organometallic metal precursor, where the temperature may be in the range of about 50° C. to about 119° C., or in the range of about 60° C. to about 119° C., or in the range of about 65° C. to about 99° C., or in the range of about 75° C. to about 99° C.

In one or more embodiments, the temperature of the organometallic metal precursor and the organometallic metal reactant may be maintained at or below the range of the deposition temperatures, and/or the substrate may be maintained at or below the range of the deposition temperatures.

One or more embodiments may involve heating a liquid organometallic metal precursor to generate the gaseous organometallic metal precursor, where the organometallic metal precursor may be contained in an ampoule or a glass or metal container that does not interact with the organometallic metal precursor.

In various embodiments, the temperature of the organometallic metal precursor and the organometallic metal reactant is at or below the reaction temperature range for the specific precursor and reactant combination, and the substrate temperature is maintained within the reaction temperature range. Maintaining the temperature of the organometallic metal precursor and the organometallic metal reactant below the reaction temperature of the substrate may reduce or prevent gaseous reactions between the metal precursor and the reactant.

In various embodiments, the temperature of the organometallic metal precursor and the organometallic metal reactant may be in the range of about 25° C. to about 150° C., or in the range of about 25° C. to about 110° C., or in the range of about 25° C. to about 90° C., and the substrate temperature may be in the range of about 60° C. to about 119° C., or in the range of about 75° C. to about 99° C.

In various embodiments, CVD of the organometallic metal precursor and the organometallic metal reactant is avoided by maintaining a deposition temperature of less than about 150° C., where the temperature of the reactant gases and/or the substrate may be maintained at a temperature of less than about 150° C., or less than about 120° C.

Principles and embodiments of the present disclosure relate to a low boiling point liquid organometallic metal precursor that can deposit various metals onto a substrate by ALD at or below temperatures used for CVD.

In embodiments of the present disclosure, the term “organometallic metal precursor” refers to the organometallic complex that deposits the metal on the substrate surface, whereas the term “organometallic metal reactant” refers to the alkyl-metal complex that reacts with the organometallic metal precursor to form the deposited metal layer.

An aspect of the present disclosure relates generally to volatile metal aminoalkoxide complexes, metal dialkoxide complexes, and metal diketonate complexes that deposit conformal metal layers on substrates at low temperatures.

In one or more embodiments, the organometallic metal precursor may be a liquid metal aminoalkoxide complex, a liquid metal dialkoxide complex or liquid metal diketonate complex, wherein each of the organic ligands bond to the metal through either an oxygen and a nitrogen coordinate bond or two oxygen coordinate bonds.

In one or more embodiments, the metal may be Cu, Ni, Co, Mn, Fe, Cr, Ru, Mo, Rh, or combinations thereof, which may be deposited on a substrate.

In various embodiments of the present disclosure, the organometallic Cu precursors include bis(diethylamino-2-n-butoxy)copper (Cu(DEAB)₂), bis(ethylmethylamino-2-n-butoxy)copper, bis(dimethylamino-2-propoxy)copper (Cu(DMAP)₂), bis(dimethylamino-2-n-butoxy)copper (Cu(DMAB)₂), bis(dimethylamino-2-ethoxy)copper, bis(ethymethylamino-2-propoxy)copper (Cu(EMAP)₂), bis(diethylamino-2-ethoxy)copper, bis(ethylmethylamino-2methyl-2-n-butoxy)copper, bis(dimethylamino-2-methyl-2-propoxy)copper, bis(diethylamino-2-propoxy) copper (Cu(DEAP)₂), bis(2-methoxyethoxy)copper, bis(2,2,6,6-tetramethyl-3,5-heptanedionate) copper, bis(2,2,6,6-tetramethyl-3,5-heptaneketoiminate) copper, bis(2-methoxy-2-propoxy)copper, and 2,2,6,6-tetramethyl-3,5-heptanedionate copper (TMVS), which may form Cu metal films when the organometallic Cu precursors are reacted with an alkyl-metal precursor including, trimethyl aluminum, triethyl aluminum, trimethyl borane, triethyl borane, and/or diethyl zinc.

One or more embodiments of the disclosure are directed to new copper precursors for ALD copper deposition processes. In some embodiments, the thermal stability of the precursors is improved by increased steric hindrance of the ligand around the copper atom. In one or more embodiments, the copper precursor has a melting point below room temperature, allowing use in bubbler applications. Without being bound by any particular theory of operation, it is believed that use with a bubbler application may allow for greater consistency of delivery throughout the deposition process.

In some embodiments, the ligand around the copper atom is asymmetrical. Without being bound by any particular theory of operation, it is believed that the asymmetrical ligands can lower the melting point of the precursor with longer alkyl groups.

Some embodiments of the disclosure are directed to copper precursors with increased thermal stability. Without being bound by any particular theory of operation, it is believed that the increased thermal stability is related to the increased steric effects.

In some embodiments, the copper precursor has a lower melting point. Without being bound by any particular theory of operation, it is believed that the lower melting point allows the precursors to be used as a liquid with increased asymmetric ligands and longer alkyl groups.

In some embodiments, the copper precursors comprise secondary aminoalkoxide derivatives with various R₁, R₂ and R₃ groups on C and N atoms in the ligand backbone. One or more embodiments of the disclosure are directed to metal coordination complexes containing copper atoms. The metal coordination complex has a formula represented by structure (I)

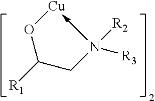

where R₁ is methyl, ethyl, iso-propyl, n-propyl or t-butyl, R₂ is methyl, ethyl, iso-propyl or n-propyl and R₃ is methyl, ethyl, iso-propyl or n-propyl. While structure (I) shows a complex with two of the same aminoalkoxide ligands, those skilled in the art will understand that the identity of the R groups on each of the ligands can be different.

In some embodiments, the metal coordination complex has a formula represented by structure (II)

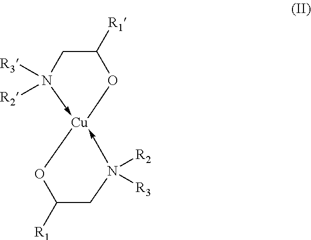

For example, the R₁ group may be a methyl in one ligand attached to the copper atom and an ethyl in the second ligand attached to the copper atom. Stated differently, with respect to structure (II), the R₁ group may be a methyl group and the R′₁ group may be an ethyl. For ease of description, the R groups that follow are representative of only one of the aminoalkoxide ligands attached to the copper atom.

In some embodiments, the copper metal coordination complex has a formula represented by structure (III)

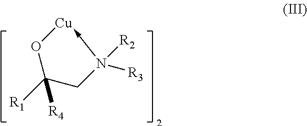

where each of R₁, R₂ and R₃ are independently methyl or ethyl, and R₄ is methyl, ethyl or propyl. In one or more embodiments, the copper metal coordination complex has a formula represented by structure (III) where R₁, R₂ and R₃ are methyl groups and R₄ is an ethyl group.

In some embodiments, R₁ is a methyl group. In embodiments of this sort, R₃ can be a methyl group and R₂ is one or more of iso-propyl or n-propyl. In one or more embodiments of this sort, R₂ is iso-propyl. In some embodiments of this sort, R₂ is n-propyl.

In some embodiments, R₁ is ethyl and R₂ is iso-propyl and R₃ is methyl.

In one or more embodiments, R₁ is iso-propyl and R₂ is methyl, ethyl or iso-propyl and R₃ is methyl. In some embodiments of this sort, R₂ is methyl. In one or more embodiments of this sort, R₂ is ethyl. In some embodiments, of this sort, R₂ is iso-propyl.

In some embodiments, R₁ is n-propyl and R₂ is methyl or ethyl and R₃ is methyl. In one or more embodiments of this sort, R₂ is methyl. In some embodiments of this sort, R₂ is ethyl.

In some embodiments, R₁ is t-butyl and R₂ is methyl and R₃ is methyl, ethyl, iso-propyl or n-propyl. In one or more embodiments of this sort, R₃ is methyl. In one or more embodiments of this sort, R₃ is ethyl. In one or more embodiments of this sort, R₃ is iso-propyl. In one or more embodiments of this sort, R₃ is n-propyl.

In one or more embodiments, the copper precursor comprises a complex according to structure (I) in which at least one of R₁, R₂ and R₃ are ethyl groups. In some embodiments, the copper precursor comprises a complex according to structure (III) in which at least one of R₁, R₂, R₃ and R₄ are ethyl groups.

In one or more embodiments, the copper-containing organometallic metal precursor compound is a liquid at temperatures greater than or equal to about 25° C., 50° C., 75° C., 100° C., 125° C., 150° C., 175° C., 200° C., 225° C., 250° C., 275° C. or 300° C. In some embodiments, the copper-containing organometallic metal precursor compound is a liquid at temperatures below or equal to about 25° C., 50° C., 75° C. or 100° C.

Additional embodiments of the disclosure are directed to processing methods that can be either CVD or ALD processes. In some embodiments, the method comprises sequentially exposing a substrate to a first reactive gas comprising a copper-containing organometallic complex and a second reactive gas to form a copper-containing film. The copper-containing organometallic complex is represented by the formula of structure (I) or (II) where R₁ is methyl, ethyl, iso-propyl, n-propyl or t-butyl, R₂ is methyl, ethyl, iso-propyl or n-propyl and R₃ is methyl, ethyl, iso-propyl or n-propyl. In one or more embodiments, the copper precursor comprises a complex according to structure (I) in which at least one of R₁, R₂ and R₃ are ethyl groups.

Further embodiments of the disclosure are directed to processing methods comprising sequentially exposing a substrate to a first reactive gas comprising a copper-containing organometallic complex and a second reactive gas to form a copper-containing film. The copper-containing organometallic complex is represented by structure (III) where each of R₁, R₂ and R₃ are independently methyl or ethyl, and R₄ is methyl, ethyl or propyl. In one or more embodiments, the copper-containing metal coordination complex has a formula represented by structure (III) where R₁, R₂ and R₃ are methyl groups and R₄ is an ethyl group. In some embodiments, the copper precursor comprises a complex according to structure (III) in which at least one of R₁, R₂, R₃ and R₄ are ethyl groups.

In some embodiments, the second reactive gas comprises one or more of a hydrogen-containing compound and the copper-containing film is a copper film. In some embodiments, the copper-containing film is substantially pure copper. As used in this regard, the term “substantially pure copper” means that film is greater than or equal to about 95 atomic percent copper, or 96 atomic percent copper, or 97 atomic percent copper, or 98 atomic percent copper or 99 atomic percent copper.

In various embodiments of the present disclosure, the organometallic Ni and Co precursors include bis(diethylamino-2-n-butoxy)nickel (Ni(DEAB)₂), bis(ethylmethylamino-2-n-butoxy)nickel (Ni(EMAB)₂), bis(dimethylamino-2-propoxy)nickel (Ni(DMAP)₂, bis(dimethylamino-2-ethoxy)nickel, bis(ethymethyllamino-2-propoxy)nickel (Ni(EMAP)₂), bis(diethylamino-2-ethoxy)nickel, bis(ethylmethylamino-2-methyl-2-n-butoxy)nickel, bis(diethylamino-2-propoxy)nickel, bis(N,N′-di-i-propylacetamidinato)cobalt, bis(diethylamino-2-n-butoxy)cobalt, bis(ethylmethylamino-2-n-butoxy)cobalt (Co(EMAB)₂), bis(ethymethyllamino-2-propoxy)cobalt (Co(EMAP)₂), and bis(dimethylamino-2-propoxy)cobalt (Co(DMAP)₂), which may form Ni or Co metal films when the organometallic precursors are reacted with an alkyl-metal precursor including, trimethyl aluminum, triethyl aluminum, trimethyl borane, triethyl borane, and/or diethyl zinc. In some embodiments, the Ni and/or Co precursors have a structure equivalent to that of structures (I), (II) or (III) with the Ni or Co replacing the Cu atom. The number of ligands surrounding the Ni or Co atom can vary depending on the oxidation states of the metal atom.

In various embodiments of the present disclosure, the organometallic Fe precursors may be Fe(III) tert-butoxide or [Fe(O-tBu)₃]₂. In some embodiments, the Fe precursor has a structure equivalent to that of structures (I), (II) or (III) with the Fe atom replacing the Cu atom. The number of ligands surrounding the Fe atom can vary depending on the oxidation states of the metal atom.

In various embodiments of the present disclosure, the organometallic Cr precursors may be Cr(III) acetylacetonate or Cr(III) tris(2,2,6,6-tetramethyl-3,5-heptanedionate). In some embodiments, the Cr precursor has a structure equivalent to that of structures (I), (II) or (III) with the Cr atom replacing the Cu atom. The number of ligands surrounding the Cr atom can vary depending on the oxidation states of the metal atom.

In various embodiments of the present disclosure, the organometallic Mn precursors may be Mn acetylacetonate.

In various embodiments of the present disclosure, the organometallic Ru precursors may be Ru acetylacetonate.

In various embodiments, the ALD material is an organometallic compound comprising an organometallic ligand that can bond to a metal through both an oxygen and a nitrogen coordinate bond.

In various embodiments, the metal bound to the organic ligand in the organometallic metal precursor compound may be selected from the group consisting of Cu, Ni, Co, Mn, Fe, Cr, and Ru. In various embodiments, the organometallic metal precursor compounds comprise Cu, Ni, or Co.

In one or more embodiments, there are no halides included on the organic ligands of the organometallic metal precursors or organometallic metal reactants. In various embodiments fluorines and/or chlorines are excluded from the organic ligands in the organometallic metal precursor compounds and organometallic metal reactants.

In one or more embodiments, the organometallic metal precursor compounds are liquids. The liquids may have a high vapor pressure, and/or low precursor delivery temperatures below 150° C. or below 120° C. or below 100° C., or below 70° C. or below 20° C. or below 0° C.

In one or more embodiments, a barrier layer comprising Ru, Mn, Co, Ta, Ni, Cr, and/or the oxides, nitrides, and carbides of Ru, Mn, Co, Ta, Ni, Cr, and combinations thereof may be deposited between the substrate and the Cu layer. In various embodiments, a barrier layer comprising a Ru layer, MnN layer, Co layer, TaN layer, and their combinations may be deposited between the substrate and the Cu layer.

In one or more embodiments, the Cu layer may be a Cu seed layer.

In various embodiments, copper may be electro-chemically deposited (ECD) onto a Cu seed layer and into trenches and vias having an ALD deposited Cu metal layer.

Principles and embodiments of the present disclosure relate to providing a deposited seed layer that has a uniform thickness over the surface feature, wherein the thickness may be in the range of about 5 Å to about 1,000 Å (100 nm) with a variation of less than 10 Å.

Another aspect of the present disclosure relates generally to a method of depositing a Cu seed layer on features formed on a substrate, wherein the Cu seed layer is continuous and conformal to the surface of the feature. In one or more embodiments, the Cu seed layer is deposited by ALD using one or more organometallic precursors and one or more organometallic reactants.

In various embodiments, the ALD deposition cycle allows monolayer or sub-monolayer control of the seed layer thickness.

In one or more embodiments, the thickness of the deposited metal may be in the range of about 0.5 Å to about 1000 Å, or in the range of about 5 Å to about 300 Å, or in the range of about 5 Å to about 50 Å.

In various embodiments, the ALD deposition cycle(s) are conducted at or below temperatures that reduce or eliminate thermal migration of metal atoms on the feature surfaces and/or agglomeration of the deposited metal. The low temperature deposition favors the seed layer growth with less agglomeration, so the seed layer can form a continuous film.

In various embodiments, the substrate temperature for deposition may be in the range of about 60° C. to about 120° C. to reduce the amount of agglomeration by deposited metal. In some embodiments using the precursors having structures equivalent to (I), (II) or (III), the temperature of the substrate during deposition can be controlled, for example, by setting the temperature of the substrate support or susceptor. In some embodiments the substrate is held at a temperature in the range of about 100° C. to about 475° C., or in the range of about 150° C. to about 350° C. In one or more embodiments, the substrate is maintained at a temperature less than about 475° C., or less than about 450° C., or less than about 425° C., or less than about 400° C., or less than about 375° C.

In one or more embodiments, the organometallic metal precursor compound is a liquid at temperatures greater than or equal to about 25° C., 50° C., 75° C., 100° C., 125° C., 150° C., 175° C., 200° C., 225° C., 250° C., 275° C. or 300° C. In some embodiments, the organometallic metal precursor compound is a liquid at temperatures below or equal to about 25° C., 50° C., 75° C., 100° C. or 125° C.

In various embodiments, the organometallic metal precursor adsorbs onto the substrate surface and deposits a metal layer without agglomerating or forming islands at the reaction temperature. In various embodiments, the reaction temperature may be in the range of about 60° C. to about 120° C., or in the range of about 75° C. to about 100° C.

Another aspect of the present disclosure is directed to liquid organometallic metal precursors that have higher vapor pressures than solid metal precursors at low temperatures.

In one or more embodiments, a liquid precursor of copper, cobalt, and/or nickel may be reacted with an alkyl-metal to deposit a copper, cobalt, and/or nickel thin film at a temperature in the range of about 60° C. to about 120° C.

In various embodiments, the substrate temperature for deposition may be in the range of about 60° C. to about 120° C. to produce a deposition rate in the range of about 0.4 Å/cycle to about 3.0 Å/cycle, where the deposition rate increases with substrate temperature.

In various embodiments, the deposition rate may be in the range of about 1.0 Å/cycle to about 1.5 Å/cycle in a range of deposition temperatures from about 80° C. to about 90° C., or the deposition rate may be in the range of about 1.4 Å/cycle to about 1.8 Å/cycle in a range of deposition temperatures from about 100° C. to about 110° C.

Principles and embodiments of the present disclosure relate to a method of depositing a continuous metal film on a substrate at temperatures at or below 200° C. without use of a plasma.

In one or more embodiments a substrate may be heated to a temperature of less than about 200° C. to avoid chemical vapor deposition of the metal on the substrate, and preferentially deposit the metal by atomic layer deposition.

In one or more embodiments, the liquid organometallic metal precursor may evaporate at temperatures in the range of about standard ambient temperature (25° C.) to about 100° C. at absolute pressure (100 kPa) (Standard Ambient Temperature and Pressure (SATP)), where the metal precursor is liquid at SATP. In various embodiments, the liquid organometallic metal precursor may evaporate at temperatures below a temperature at which they decompose.

In one or more embodiments, the liquid metal precursor may be retained in a bubbler ampoule to generate a higher vapor pressure of precursor at a lower temperature for introduction into a reaction chamber.

In various embodiments, the substrate temperature may be in the range of about 50° C. to about 150° C., which may be lower than a substrate used for metal deposition from a solid precursor.

In one or more embodiments, a monolayer or sub-monolayer of a metal precursor may be deposited on a surface feature having a size in the range of about 2 nm to about 22 nm and an aspect ratio of up to and including 10:1 and reacted with an alkyl metal precursor to form a continuous, conformal metal layer on the surface feature.

In one or more embodiments, a monolayer or sub-monolayer of a metal precursor may be deposited on a surface feature having a top opening in the range of about 2 nm to about 22 nm and an aspect ratio of up to and including 10:1 and reacted with an alkyl metal precursor to form a continuous, conformal metal layer on the surface feature.

In one or more embodiments, the amount of metal precursor adsorbed onto the substrate surface may be controlled by adjusting the partial pressure of the metal precursor and/or the amount of time the substrate surface is exposed to the gaseous metal precursor, where lower partial pressures and/or shorter exposure times may be used to produce sub-monolayer coverage, or higher partial pressures and/or longer exposure times may be used to produce saturated (i.e., monolayer) coverage.

In various embodiments, the surface features may be trenches having dimensions of 20 nm or less and/or vias having dimensions of 3 nm or less. The surface features may have aspect ratios up to and including 10:1.

In one or more embodiments, a continuous, conformal layer of Cu may be deposited on a substrate surface at a deposition temperature in the range of about 60° C. to about 150° C. without use of a plasma, wherein the Cu layer may have a thickness in the range of about 0.5 Å to about 1000 Å, and the purity of the deposited conformal Cu layer may be greater than 99%, or greater than 99.5% Cu. In various embodiments the concentration of contaminants in the conformal Cu layer may be less than 0.5%, where the contaminants may be carbon, nitrogen, and oxygen, or a combination thereof. The resistivity of the deposited Cu may be <2 μΩ/cm. In various embodiments, the Cu layer may have a thickness in the range of about 0.5 Å to about 500 Å, or in the range of about 0.5 Å to about 50 Å.

In one or more embodiments, the Cu layer deposited at temperatures in the range of about 60° C. to about 120° C. forms essentially no alloys with the Zn, B, or Al, of the alkyl metal precursor. In various embodiments, the gaseous organometallic metal reactant is an alkyl aluminum compound, an alkyl boron compound, or an alkyl zinc compound, and the substrate is heated to a temperature in the range of about 60° C. to about 100° C. In various embodiments, the gaseous organometallic metal reactant is an alkyl aluminum compound and the substrate is heated to a temperature in the range of about 60° C. to about 100° C. In various embodiments, the gaseous organometallic metal reactant is triethyl aluminum, and the substrate is heated to a temperature in the range of about 65° C. to about 95° C.

In one or more embodiments, a metal layer may be deposited at temperatures in the range of about 75° C. to about 100° C. when reacting a organometallic metal precursor (e.g., Cu(DMAP)₂, Cu(EMAP)₂, Cu(DEAB)₂) with an alkyl aluminum organometallic reactant (e.g., Al(CH₃)₃, Al(C₂H₅)₃).

In one or more embodiments, a monolayer of an organometallic metal precursor compound comprising a metal selected from the group consisting of Cu, Ni, Co, Mn, Fe, Cr, Ru, Mo, and Rh, and an organic ligand which may bond to the metal through both an oxygen and a nitrogen coordinate bond may be formed on a substrate, and the organometallic compound exposed to an alkyl metal reactant comprising a metal selected from the group consisting of aluminum, boron, and zinc, and an alkyl ligand having the formula of CₓH₂ₓ₊₁, where x=1 or 2 (i.e., methyl or ethyl).

In one or more embodiments, the gaseous organometallic metal reactant may be an alkyl aluminum compound, an alkyl boron compound, or an alkyl zinc compound. In various embodiments, the organometallic metal reactant may be heated to form a vapor.

In one or more embodiments, the organometallic metal reactant may be an alkyl aluminum compound, including Al(CH₃)₃ or Al(C₂H₅)₃.

In one or more embodiments, the organometallic metal reactant may be an alkyl boron compound, including B(CH₃)₃ or B(C₂H₅)₃.

In one or more embodiments, the organometallic metal reactant may be an alkyl zinc compound, including Zn(C₂H₅)₃.

In various embodiments, the organometallic metal precursor compound may be volatile metal aminoalkoxide complexes.

In one or more embodiments, the substrate may be sequentially and repetitively exposed to the organometallic metal precursor and the alkyl metal reactant to deposit multiple monolayers on the substrate.

In one or more embodiments, a metal layer may be built up monolayer by monolayer by repeating the exposure of the surface to the metal aminoalkoxide complex and the alkyl metal precursor until an intended thickness of the metal has been deposited.

In various embodiments, the intended thickness may be in the range of about 0.5 Å to about 1000 Å, where the minimum metal layer thickness may depend upon the atomic diameter of the metal being deposited. For example, when forming a single monolayer, the metal layer may have a thickness of approximately one atomic diameter of the deposited metal.

In various embodiments, the conformal metal film provides step coverage of 95% or greater, or 98% or greater, or 99% or greater, or 100%.

In one or more embodiments, copper may be electro-chemically deposited onto a Cu seed layer, and into conformally coated trenches and vias.

In an exemplary embodiment, a substrate comprising a semiconductor wafer having trenches and vias with dimensions of less than 20 nm has a 15 Å layer of TaN deposited on the surface. A 15 Å layer of Ru is deposited on the TaN layer. The substrate is maintained at a temperature of about 85° C. and exposed to a Cu(DMAP)₂ precursor and a triethyl aluminum (TEA) precursor in the range of 70 to 200 cycles to deposit a controlled thickness of a Cu seed layer, where the Cu seed layer is conformal and provides gap filling without voids and pinched-off spaces, and has a purity of greater or equal to 99.5%.

In an exemplary embodiment, a method may comprise placing a substrate having a substrate surface within a reaction chamber, heating the substrate to a temperature in the range of about 75° C. to about 99° C., introducing gaseous Cu(EMAP)₂ into the reaction chamber, wherein at least a portion of the substrate surface is exposed to the gaseous Cu(EMAP)₂, adsorbing the Cu(EMAP)₂ onto at least a portion of the substrate surface, wherein the adsorbed Cu(EMAP)₂ forms a continuous and conformal Cu(EMAP)₂ film on the substrate surface, introducing gaseous trimethyl aluminum (TMA) or triethyl aluminum into the reaction chamber, wherein at least a portion of the continuous and conformal Cu(EMAP)₂ film on the substrate surface is exposed to the gaseous trimethyl aluminum or triethyl aluminum, and reacting the Cu(EMAP)₂ with trimethyl aluminum or triethyl aluminum to deposit a Cu metal layer on the substrate surface, wherein the Cu metal layer has a thickness in the range of about 5 Å to about 1,000 Å, and a purity of greater than 99.5%.

In another exemplary embodiment, a method may comprise placing a substrate having a substrate surface within a reaction chamber, heating the substrate to a temperature in the range of about 75° C. to about 99° C., introducing gaseous Cu(EMAB)₂ into the reaction chamber, wherein at least a portion of the substrate surface is exposed to the gaseous Cu(EMAB)₂, adsorbing the Cu(EMAB)₂ onto at least a portion of the substrate surface, wherein the adsorbed Cu(EMAB)₂ forms a continuous and conformal Cu(EMAB)₂ film on the substrate surface, introducing gaseous trimethyl aluminum or triethyl aluminum into the reaction chamber, wherein at least a portion of the continuous and conformal Cu(EMAB)₂ film on the substrate surface is exposed to the gaseous trimethyl aluminum or triethyl aluminum, and reacting the Cu(EMAB)₂ with trimethyl aluminum or triethyl aluminum to deposit a Cu metal layer on the substrate surface, wherein the Cu metal layer has a thickness in the range of about 5 Å to about 1,000 Å, and a purity of greater than 99.5%.

While the exemplary embodiments describe copper amino alkoxide complexes, it is to be understood that the other metals including Ni and Co may also be used, for example Ni(EMAB)₂, Ni(EMAP)₂, Ni(DMAP)₂, Co(EMAB)₂, Co(EMAP)₂, and Co(DMAP)₂.

In various embodiments, the trenches and vias may be filled by ECD of Cu onto the Cu seed layer without the formation of voids.

In various embodiments, additional layers of different metals may be formed by ALD.

Various exemplary embodiments of the disclosure are described in more detail with reference to the figures. It should be understood that these drawings only illustrate some of the embodiments, and do not represent the full scope of the present disclosure for which reference should be made to the accompanying claims.

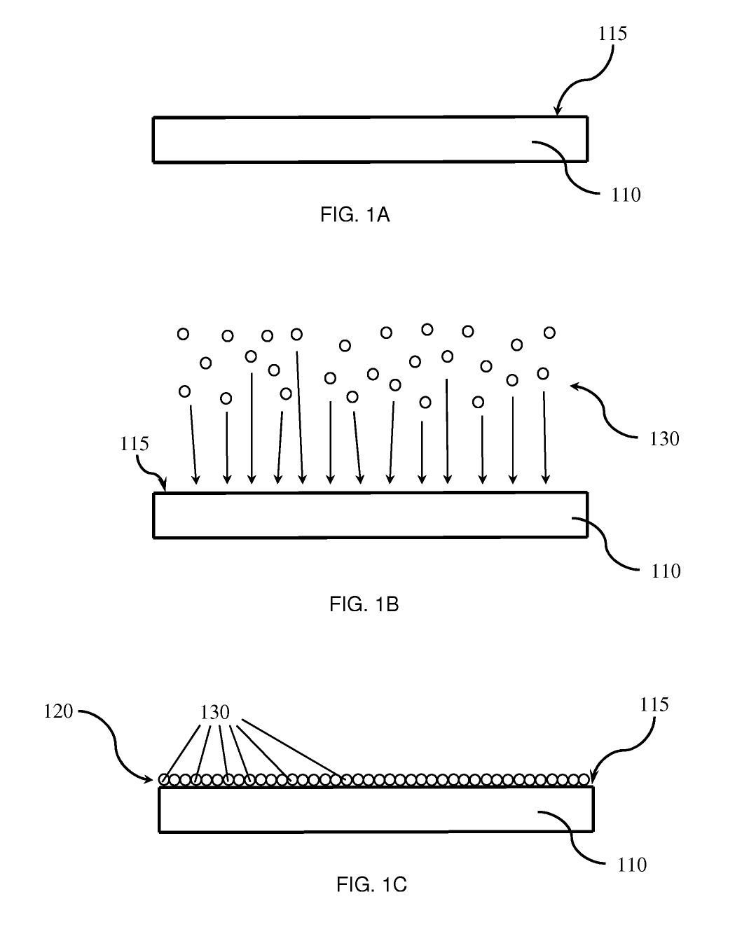

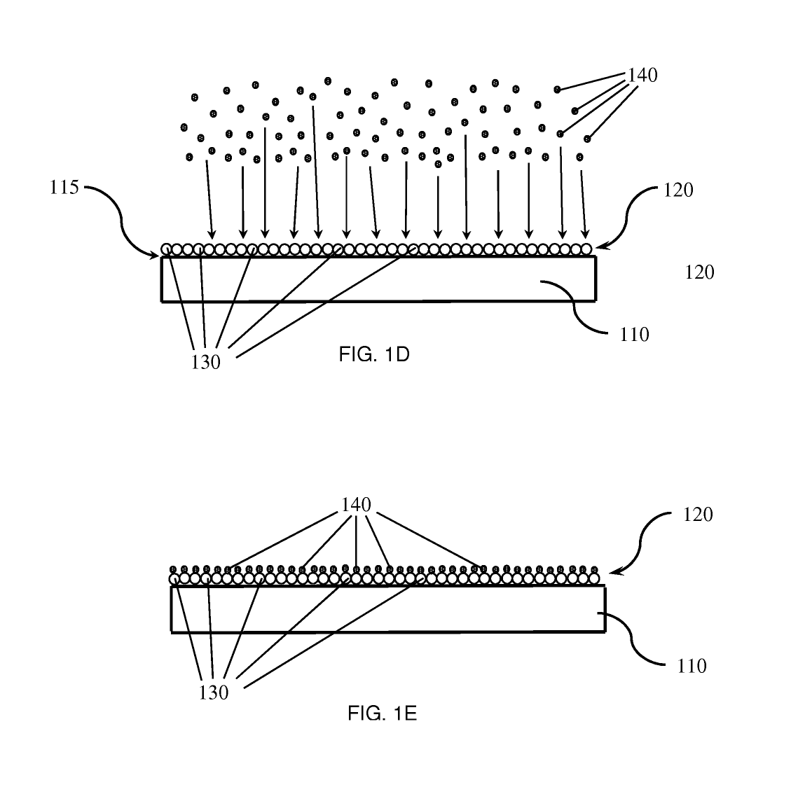

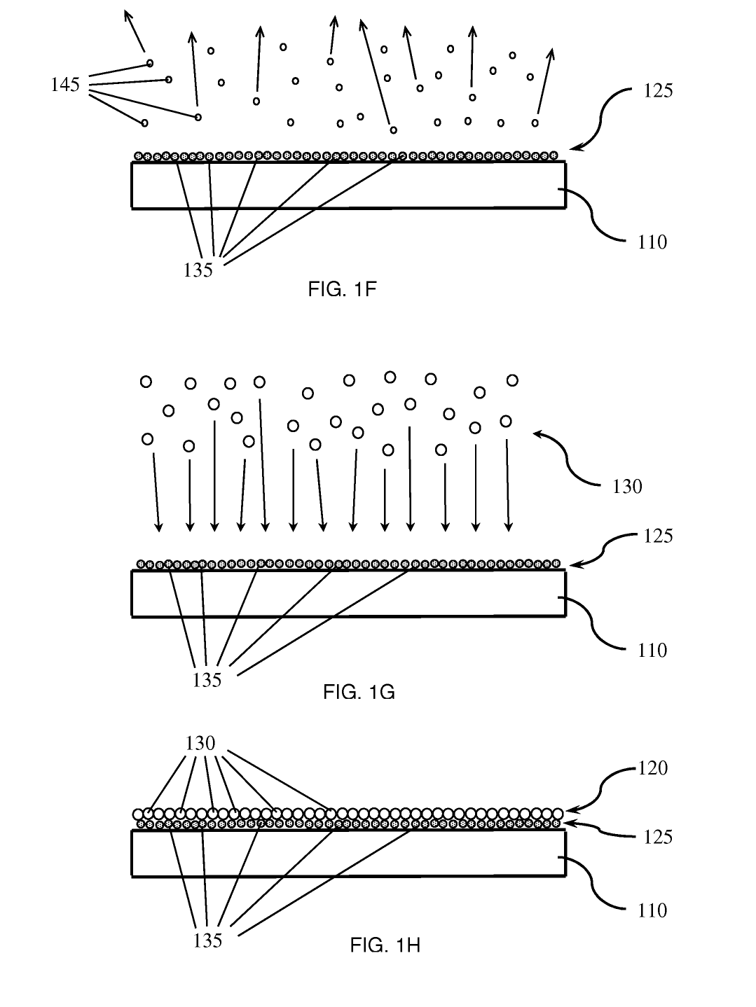

FIGS. 1A-1H illustrate an exemplary embodiment of a metal ALD deposition on a substrate surface.

FIG. 1A illustrates an exemplary embodiment of a substrate 110 having a surface 115 that may be exposed for subsequent processing. In one or more embodiments, the substrate may be an unprocessed semiconductor wafer, a semiconductor wafer that has front end of line processes conducted on it, or a semiconductor wafer that has had back end of line processes conducted on it.

In various embodiments the substrate may be a wafer that has one or more additional layers formed and/or deposited on the wafer, such as insulating layers, epitaxial layers, strained layers, high-k dielectric layers, etch-stop layers, or any combination thereof. For example, the substrate may be a silicon-on-insulator (SOI) or semiconductor on insulator (SeOI) wafer with one or more device layers deposited and/or patterned on the SOI layer(s).

In various embodiments, the substrate material(s) may comprise for example, silicon, strained silicon, germanium, gallium arsenide, gallium nitride, silicon carbide, silicon oxide, silicon nitride, silicon oxy-nitride, aluminum oxide, hafnium dioxide, hafnium silicate, zirconium dioxide, zirconium silicate, titanium nitride, titanium carbide, tantalum nitride, tantalum carbide, tantalum, chromium, niobium, cobalt, and ruthenium.

In various embodiments, trenches and/or vias may have been formed in the substrate surface to receive a metal deposition to form electrical connections.

In various embodiments, one or more barrier layers may be deposited on the substrate and/or surface features prior to depositing a metal seed layer, where the barrier layer may be for example tantalum, tantalum nitride, tantalum carbide, titanium nitride, titanium carbide, or ruthenium nitride.

FIG. 1B illustrates an exemplary embodiment of the exposure of the substrate to a gaseous organometallic metal precursor 130 that conformally adsorbs to the substrate surface 115.

In various embodiments, the organometallic metal precursor may be a volatile organometallic liquid that can generate a vapor pressure above the substrate surface 115. The organometallic metal precursor molecules 130 may adsorb to the exposed portions of the surface that provide suitable binding interactions, for example dipole-dipole interactions, for the organometallic metal precursor molecules.

In one or more embodiments, the ALD deposition may be conducted within a suitable reaction chamber that may provide reduced pressures, such as a low vacuum chamber (760 torr to 25 torr), a medium vacuum chamber (25 torr to 1×10⁻³ torr) a high vacuum chamber (1×10⁻³ torr to 1×10⁻⁸ torr), or an ultra-high vacuum chamber (1×10⁻⁸ torr to 1×10⁻¹² torr), that may be evacuated by suitable vacuum pumps.

FIG. 1C illustrates an exemplary embodiment of a monolayer film 120 of an organometallic metal precursor 130 adsorbed to the surface 115 of the substrate 110. In various embodiments, less than a monolayer (i.e., a sub-monolayer) of the organometallic metal precursor 130 may adsorb onto the surface 115 by reducing the exposure time and/or partial pressure of the organometallic metal precursor 130 above the substrate 110. In one or more embodiments, the surface 115 of the substrate 110 would become saturated with the organometallic metal precursor molecules 130 to form a monolayer film 120 at a specified temperature and pressure within a period of time based on the competing rates of adsorption and desorption. In ALD the formation of a monolayer would be self-limiting in that additional metal precursor(s) would not adsorb onto metal precursors already adsorbed to the substrate.

In one or more embodiments, the organometallic metal precursor may be a copper metal precursor, a nickel metal precursor, a cobalt metal precursor, or combinations thereof.

In one or more embodiments, the organometallic metal precursor may be an iron metal precursor, a nickel metal precursor, a cobalt metal precursor, or combinations thereof.

FIG. 1D illustrates an exemplary embodiment of the exposure of an adsorbed monolayer film 120 of organometallic metal precursors 130 to a gaseous organometallic metal reactant 140.

In various embodiments, the self-limiting formation of monolayers allows precise control of a final layer's thickness by managing the total number of exposure cycles of the substrate to the organometallic metal precursor and the gaseous organometallic reactant. In various embodiments, the deposition of a metal layer may involve from 1 to 1000 cycles, or from 5 to 500 cycles, or from 10 to 300 cycles, or from 20 to 200 cycles, where a cycle may comprise a sequential exposure of a surface to an organometallic metal precursor and an organometallic metal reactant.

FIG. 1E illustrates an exemplary reaction between the deposited organometallic metal precursor 130 forming a monolayer film 120 on the substrate surface, and the organometallic metal reactant 140 reacting with the organometallic metal precursor 130, where the reaction is self-limiting. In one or more embodiments, the organometallic metal reactant molecules 140 react preferentially with the adsorbed organometallic metal precursor molecules 130 in a stoichiometric relationship to deposit the metal of the organometallic metal precursor onto the substrate surface 115.

FIG. 1F illustrates an exemplary desorption of volatile organic and/or organometallic products 145 from the layer of the deposited metal 125 (e.g., Cu, Ni, Co, Mn, Fe, Cr, Ru, Mo, or Rh). In various embodiments, the deposited metal forms a continuous, conformal, metal layer 125 on the substrate, where the metal layer may be a monolayer or sub-monolayer depending on the coverage of the surface with the organometallic metal precursor 130.

FIG. 1G illustrates an exemplary repeated exposure of the now deposited metal monolayer 125 on the surface 115 of the substrate 110 to another cycle of the organometallic metal precursor 130. The exposure of the exposed surface of the metal monolayer 125 to another dose of gaseous organometallic metal precursor 130 may form a monolayer or sub-monolayer film 120 of organometallic metal precursor 130 on the previously deposited metal atoms 135, which formed the continuous and conformal metal monolayer 125.

FIG. 1H illustrates an exemplary adsorption of a monolayer film 120 of the gaseous organometallic metal precursor 130 on the metal monolayer 125. In a similar manner, the adsorbed organometallic metal precursor monolayer 120 may be subsequently exposed to another cycle of the gaseous organometallic metal reactant 140.

An aspect of the present disclosure relates generally to a method of depositing continuous, conformal metal layers comprising exposing a substrate surface sequentially to a first organometallic metal precursor to produce a single layer of first organometallic metal precursor molecules bound to the substrate surface, exposing the single layer of first organometallic metal precursor molecules bound to the substrate surface to a first organometallic metal reactant, where the first organometallic metal reactant molecules react preferentially with the first organometallic metal precursor molecules bound to the substrate surface, repeating the sequential exposure of the substrate surface to the first organometallic metal precursor molecules and the first organometallic metal reactant molecules until a continuous, conformal, metal layer with an intended thickness is produced on the substrate surface.

In various embodiments, the method comprises repeating exposure of the substrate and previously deposited metal layer to the gaseous organometallic metal precursor and gaseous organometallic metal reactant to deposit additional monolayers or sub-monolayers of the metal. Repeating a cycle of introducing the organometallic metal precursor to expose the substrate surface and introducing the organometallic metal reactant forms additional metal layers on previously deposited metal layers.

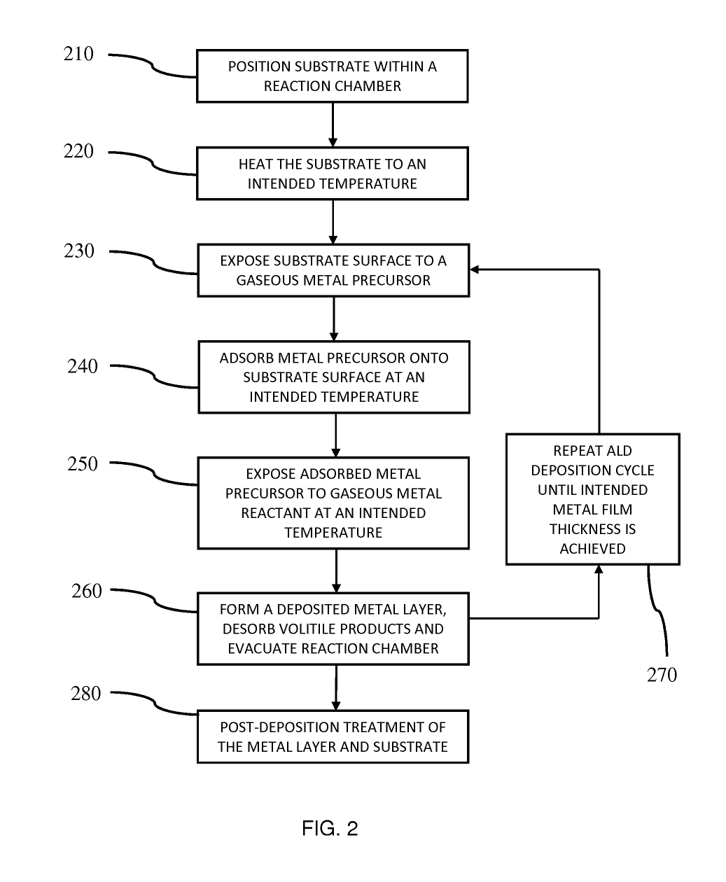

FIG. 2 illustrates a flow chart for an exemplary embodiment of a continuous and conformal metal layer ALD deposition process.

At 210 a substrate may be placed within a reaction chamber that is suitable for an ALD deposition process. The chamber may comprise an internal volume that may be sealed and evacuated by vacuum pumps, a susceptor for holding one or more substrates (e.g., wafers), and an injector for delivering the organometallic metal precursor and organometallic reactant to the reaction chamber and/or wafer surface.

At 220 the substrate may be heated to an intended temperature at which the organometallic metal precursor will adsorb onto the substrate surface and react with the organometallic reactant to deposit the metal layer on the substrate surface.

In various embodiments, the substrate may be heated to the intended temperature by heat lamps and/or by conductive heating from the susceptor holding the substrate. Heating may be monitored by suitably located thermocouples and/or pyrometers that may be arranged externally, within the chamber, and/or operatively associated with the chamber components.

At 230 the organometallic metal precursor may be introduced into the reaction chamber, so that the substrate surface may be exposed to the gaseous organometallic metal precursor.

In one or more embodiments, the organometallic metal precursor may be a liquid at standard ambient room temperature and pressure. In various embodiments, the liquid organometallic metal precursor may be contained in receptacle, for example an ampoule, such that the organometallic metal precursor may be heated to increase the volatilization and vapor pressure of the organometallic metal precursor, and generate a gaseous organometallic precursor that may be introduced to the reaction chamber.

In one or more embodiments, the organometallic metal precursor may be a solid at standard ambient room temperature and pressure. In various embodiments, the solid organometallic metal precursor may be contained in receptacle, and may be heated to increase the volatilization and vapor pressure of the organometallic metal precursor, and generate a gaseous organometallic precursor that may be introduced to the reaction chamber.

In one or more embodiments, the gaseous organometallic metal precursor is introduced into the reaction chamber through an ALD injector, which directs the gaseous organometallic metal precursor towards at least a portion of the substrate surface. In various embodiments, the gaseous organometallic metal precursor may be direct towards the substrate surface, for example by an ALD injector, without filling a reaction chamber with the organometallic metal precursor. In various embodiments, the gaseous organometallic metal precursor may be evacuated through vacuum channel(s) before filling a reaction chamber and/or exposing portions of a substrate not under the injector delivery channel(s).

In one or more embodiments the organometallic metal precursor may be an organometallic Cu, Ni, Co, Mn, Fe, Cr, Ru, Mo, or Rh precursor.

In one or more embodiments, the organometallic Cu precursor may be selected from the group consisting of bis(diethylamino-2-n-butoxy)copper (Cu(DEAB)₂), bis(ethylmethylamino-2-n-butoxy)copper (Cu(EMAB)₂), bis(diethylamino-2-propoxy)copper (Cu(DEAP)₂), bis(dimethylamino-2-propoxy)copper (Cu(DMAP)₂), bis(dimethylamino-2-ethoxy)copper, bis(ethymethyllamino-2-propoxy)copper, bis(diethylamino-2-ethoxy)copper, bis(ethylmethylamino-2methyl-2-n-butoxy)copper, bis(dimethylamino-2-methyl-2-propoxy)copper, bis(diethylamino-2-propoxy) copper, bis(2-methoxyethoxy)copper, bis(2,2,6,6-tetramethyl-3,5-heptanedionate) copper, bis(2,2,6,6-tetramethyl-3,5-heptaneketoiminate) copper, bis(2-methoxy-2-propoxy)copper, and 2,2,6,6-tetramethyl-3,5-heptanedionate copper (TMVS), and combinations thereof.

In one or more embodiments, the organometallic Cu precursor may be reacted with trimethyl aluminum or triethyl aluminum.

In one or more embodiments, the organometallic Cu precursor may be reacted with trimethyl borane or triethyl borane.

In one or more embodiments, the organometallic Cu precursor may be reacted with diethyl zinc.

In one or more embodiments, the organometallic Ni precursor may be selected from the group consisting of bis(diethylamino-2-n-butoxy)nickel, bis(ethylmethylamino-2-n-butoxy)nickel (Ni(EMAB)₂), bis(dimethylamino-2-propoxy)nickel (Ni(DMAP)₂), bis(dimethylamino-2-ethoxy)nickel, bis(ethymethyllamino-2-propoxy)nickel (Ni(EMAP)₂), bis(diethylamino-2-ethoxy)nickel, bis(ethylmethylamino-2methyl--2-n-butoxy)nickel, and bis(diethylamino-2-propoxy)nickel, and combinations thereof.

In one or more embodiments, the organometallic Ni precursor may be reacted with trimethyl aluminum or triethyl aluminum.

In one or more embodiments, the organometallic Ni precursor may be reacted with trimethyl borane or triethyl borane.

In one or more embodiments, the organometallic Ni precursor may be reacted with diethyl zinc.

In one or more embodiments, the organometallic Co precursor may be selected from the group consisting of bis(N,N′-di-i-propylacetamidinato)cobalt, bis(diethylamino-2-n-butoxy)cobalt, bis(ethylmethylamino-2-n-butoxy)cobalt (Co(EMAB)₂), and bis(dimethylamino-2-propoxy)cobalt (Co(DMAP)₂), and combinations thereof.

In one or more embodiments, the organometallic Co precursor may be reacted with trimethyl aluminum or triethyl aluminum.

In one or more embodiments, the organometallic Co precursor may be reacted with trimethyl borane or triethyl borane.

In one or more embodiments, the organometallic Co precursor may be reacted with diethyl zinc.

At 240 the organometallic metal precursor may be adsorbed onto the substrate surface, wherein the adsorbed organometallic precursors may form a continuous and conformal film on the substrate surface. In various embodiments, the adsorption process may be a physisorption interaction. In various embodiments, the adsorption process may be a chemisorption interaction. In various embodiments, the organometallic metal precursor may interact with the substrate surface at one or more binding sites, and/or through for example dipole-dipole interactions.

In one or more embodiments, the adsorption is self-limiting, such that a mono-layer or sub-monolayer of the organometallic metal precursor forms on the substrate surface. In various embodiments, additional exposure to the gaseous organometallic metal precursor does not produce thicker layers of adsorbed organometallic metal precursor within the intended reaction temperature range.

At 250 the organometallic metal reactant may be introduced into the reaction chamber, so that the substrate surface and or film of adsorbed organometallic metal precursor may be exposed to the gaseous organometallic metal reactant.

In various embodiments, the gaseous organometallic metal reactant may be direct towards the substrate surface, for example by an ALD injector, without filling a reaction chamber with the organometallic metal precursor. In various embodiments, the gaseous organometallic metal precursor may be evacuated through vacuum channel(s) before filling a reaction chamber and/or exposing portions of a substrate not under the injector delivery channel(s)

In one or more embodiments, the organometallic metal reactant may be trimethyl aluminum or triethyl aluminum.

In one or more embodiments, the organometallic metal reactant may be trimethyl aluminum.

In one or more embodiments, the organometallic metal reactant may be trimethyl borane or triethyl borane.

In one or more embodiments, the organometallic metal reactant may be diethyl zinc.

In one or more embodiments the organometallic Cu metal precursor may be reacted with trimethyl aluminum or triethyl aluminum at a temperature in the range of about 75° C. to about 99° C. to form a deposited continuous and conformal metal layer on the substrate, wherein the conformal metal layer may be deposited at a rate in the range of about 1.0 Å/cycle to about 1.2 Å/cycle at a temperature in the range of about 75° C. to about 99° C.

In one or more embodiments the organometallic Ni metal precursor may be reacted with trimethyl aluminum or triethyl aluminum at a temperature in the range of about 75° C. to about 99° C. to form a deposited continuous and conformal metal layer on the substrate, wherein the conformal metal layer may be deposited at a rate in the range of about 1.0 Å/cycle to about 1.2 Å/cycle at a temperature in the range of about 75° C. to about 99° C.

In one or more embodiments the organometallic Co metal precursor may be reacted with trimethyl aluminum or triethyl aluminum at a temperature in the range of about 75° C. to about 99° C. to form a deposited conformal metal layer on the substrate, wherein the conformal metal layer may be deposited at a rate in the range of about 1.0 Å/cycle to about 1.2 Å/cycle at a temperature in the range of about 75° C. to about 99° C.

At 260 the organometallic metal precursor may reacted with the organometallic metal reactant to deposit a continuous and conformal metal layer on the substrate surface, wherein the deposited metal layer may be a monolayer or sub-monolayer thick and 99.0% or greater metal purity, or 99.5% or greater metal purity. The reaction of the organometallic metal precursor with the organometallic metal reactant to deposit the metal layer on the substrate surface completes an ALD cycle of exposures and reaction.

In various embodiments, an organometallic metal compound comprising the metal from the organometallic metal reactant and/or one or more organic compounds may desorb from the substrate surface and/or deposited metal layer at the reaction temperature of the substrate. The desorbed compounds may be evacuated from the reaction chamber.

In various embodiments, the metal layer formed on the substrate surface may conform to various surface features, including the sidewalls and bottom wall of one or more trenches formed in the substrate surface, and the sidewalls of one or more vias formed in the substrate surface, such that an essentially uniform monolayer or sub-monolayer of metal is deposited on all exposed substrate surfaces per cycle. In various embodiments, the isotropic and self-limiting nature of the adsorption of the gaseous organometallic metal precursor on exposed surfaces may produce an essentially uniform monolayer of adsorbed organometallic metal precursor on both horizontal and vertical surface features, as well as other features at various angles, that forms a conformal metal layer on such surfaces when reacted with the organometallic reactant.

At 270 the cycle of introducing the organometallic metal precursor to expose the substrate surface and introducing the organometallic metal reactant to form additional metal layers on the substrate surface at the reaction temperature may be repeated one or more times to form a deposited metal layer of an intended thickness. In various embodiments, the exposure and deposition cycle may be repeated a sufficient number of times to form a metal layer with a thickness in the range of about 5 Å to about 300 Å.

At 280 a post-deposition treatment of the metal layer and/or substrate may be conducted.

In one or more embodiments, a metal may be deposited by ECD onto the ALD deposited metal layer. The ECD deposited metal (e.g., Cu, Ni, Co) may fill trenches and/or vias formed in the substrate surface, which were not previously filled by ALD metal deposition.

In various embodiments, the formed metal layer and/or substrate may be etched and/or electromechanically polished to remove excess material in a post-deposition treatment.

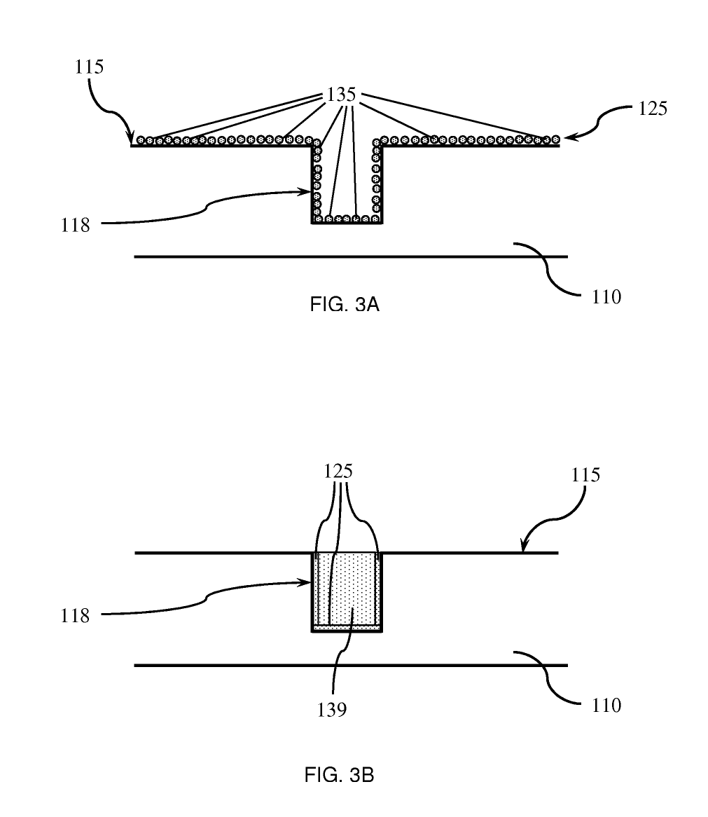

FIGS. 3A-B illustrates an exemplary embodiment of the deposition of metal layers by ALD and ECD to fill an exemplary surface feature.

FIG. 3A illustrates a conformal metal layer 125 of metal atoms 135 deposited by an ALD reaction between an organometallic metal precursor and an organometallic metal reactant over a surface feature 118, which may be a trench, via, or fabricated electronic structure, for example a FINFET.

In one or more embodiments, one or more continuous, conformal monolayer(s) of metal 125 may be deposited on the top surface, sidewalls, and bottom surface of a surface feature 118 formed in the substrate 110. In various embodiments, the surface features 118 may be trenches and/or vias to be filled with a metal interconnect.

In various embodiments, the volume of the surface feature(s) 118 formed by the feature sidewalls, feature bottom (for a trench), and substrate surface may be filled by a number of ALD cycles depositing a plurality of metal monolayers 125, or a continuous, conformal metal seed layer may be formed on the surface feature 118, and a bulk metal 139 deposited, for example by ECD, to fill the surface feature up to the plane of the substrate surface. In various embodiments, the surface feature may be filled above the plane of the substrate surface, and excess metal etched and/or polished (e.g., by chemical-mechanical polishing (CMP)) away, so the top surface of the metal 125,139 filling the feature is coplanar with the substrate surface.

FIG. 3B illustrates an exemplary embodiment of a surface feature (e.g., a trench) with a conformal metal layer 125 formed by ALD and a bulk metal 139 deposited by ECD filling the volume of the feature remaining after the ALD metal deposition cycle(s).

In one or more embodiments, additional layers may be deposited on the substrate surface between the substrate and the deposited organometallic metal precursor film, including barrier layers or liners, wherein the barrier layer may be a metal or metal nitride.

### EXAMPLE

A 30 nm thick Cu film was deposited using Cu(DMAP)₂. Deposition was conducted by heating the substrate to temperatures in the range of 80° C. to 120° C., and introducing the Cu(DMAP)₂ and organometallic aluminum metal reactant (triethylaluminum). Analysis of the deposited 30 nm Cu film showed a resistivity of less than 4.7 μΩ-cm, and Secondary Ion Mass Spectrometry (SIMS) showed impurity levels for oxygen, carbon, nitrogen, and other metals to be less than 1% (i.e., a Cu purity greater than 99%). SIMS analysis was performed with a Cs primary source and a copper standard to calibrate C, O and N concentration profiles. The detection limit of the impurities was 1E10-1E16 atoms/cm³.

Comparison of the film produced by the process described herein to a known method involving pure thermal processes without plasma-enhancement demonstrated that the method described herein produced a Cu film at 30 nm with a resistivity of 4.7 μΩ-cm compared to a Cu film with a thickness of 80 nm and a resistivity of 4.7 μΩ-cm produced by a known method. In addition, the film produced by the known method showed impurities of greater than 10% C, N, O, and metals at 30 nm thickness, and a resistivity two order of magnitude greater than the film produced by the process described herein.

It will be recognized that the processes, materials and devices of embodiments of the disclosure provide several advantages over currently known processes, materials and devices for photoresist.

Although the disclosure herein has been described with reference to particular embodiments, it is to be understood that these embodiments are merely illustrative of the principles and applications of the present disclosure. It will be apparent to those skilled in the art that various modifications and variations can be made to the material, method, and apparatus of the present disclosure without departing from the spirit and scope of the disclosure. Thus, it is intended that the present disclosure include modifications and variations that are within the scope of the appended claims and their equivalents.

What is claimed is:

1. A method comprising:
heating a substrate to a temperature in the range of about 60° C. to about 150° C.;
exposing at least a portion of a surface of the substrate to a gaseous organometallic metal precursor to form a film of the organometallic metal precursor on the surface of the substrate, wherein the organometallic metal precursor is a metal aminoalkoxide complex, a metal dialkoxide complex or metal diketonate complex; and
exposing a gaseous organometallic metal reactant to the film of the organometallic metal precursor to form a metal layer on the substrate.

2. The method of claim 1, wherein the film is a monolayer or sub-monolayer of the organometallic metal precursor, and the metal layer is a monolayer or sub-monolayer.

3. The method of claim 2, which further comprises repeating exposure of the substrate and previously deposited metal layer to the gaseous organometallic metal precursor and gaseous organometallic metal reactant to deposit additional monolayers or sub-monolayers of the metal.

4. The method of claim 1, wherein the metal aminoalkoxide complex, metal dialkoxide complex, and metal diketonate complex, is a liquid at temperatures greater than about 50° C., and wherein each organic ligand bonds to the metal through either an oxygen and a nitrogen coordinate bond or two oxygen coordinate bonds.

5. The method of claim 4, wherein the metal aminoalkoxide complexes, metal dialkoxide complexes, and metal diketonate complexes do not contain any halides, and are a liquid at standard ambient temperature and pressure.

6. The method of claim 5, wherein the metal is Cu, and the organometallic metal precursor is selected from the group consisting of bis(diethylamino-2-n-butoxy)copper, bis(ethylmethylamino-2-n-butoxy)copper, bis(dimethylamino-2-n-butoxy)copper, Cu(DMAP)₂, bis(dimethylamino-2-ethoxy)copper, bis(ethymethyllamino-2-propoxy)copper, bis(diethylamino-2-ethoxy)copper, bis(ethylmethylamino-2-methyl-2-n-butoxy)copper, bis(dimethylamino-2-methyl-2-propoxy)copper, bis(diethylamino-2-propoxy) copper, bis(2-methoxyethoxy)copper, bis(2,2,6,6-tetramethyl-3,5-heptanedionate) copper, bis(2,2,6,6-tetramethyl-3,5-heptaneketoiminate) copper, bis(2-methoxy-2-propoxy)copper, and 2,2,6,6-tetramethyl-3,5-heptanedionate copper (TMVS), and combinations thereof.

7. The method of claim 6, wherein the gaseous organometallic metal reactant is an alkyl aluminum compound and the substrate is heated to a temperature in the range of about 60° C. to about 100° C.

8. The method of claim 7, wherein the gaseous organometallic metal reactant is triethyl aluminum, and the substrate is heated to a temperature in the range of about 65° C. to about 95° C.

9. The method of claim 5, wherein the metal is Ni, and the organometallic metal precursors is selected from the group consisting of bis(diethylamino-2-n-butoxy)nickel (Ni(DEAB)₂), bis(ethylmethylamino-2-n-butoxy)nickel, bis(dimethylamino-2-propoxy)nickel, bis(dimethylamino-2-ethoxy)nickel, bis(ethymethyllamino-2-propoxy)nickel, bis(diethylamino-2-ethoxy)nickel, bis(ethylmethylamino-2-methyl-2-n-butoxy)nickel, bis(diethylamino-2-propoxy)nickel, bis(N,N′-di-i-propylacetamidinato)cobalt, bis(diethylamino-2-n-butoxy)cobalt, bis(ethylmethylamino-2-n-butoxy)cobalt, bis(dimethylamino-2-propoxy)cobalt, and combinations thereof.

10. The method of claim 5, wherein the metal is Co, and the organometallic metal precursors is selected from the group consisting of bis(N,N′-di-i-propylacetamidinato)cobalt, bis(diethylamino-2-n-butoxy)cobalt, bis(ethylmethylamino-2-n-butoxy)cobalt, bis(dimethylamino-2-propoxy)cobalt and combinations thereof.

11. The method of claim 1, wherein the organometallic metal precursor has a formula represented by 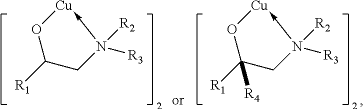
where R₁ is methyl, ethyl, iso-propyl, n-propyl or t-butyl, R₂ is methyl, ethyl, iso-propyl or n-propyl and R₃ is methyl, ethyl, iso-propyl or n-propyl, and if present, R₄ is methyl, ethyl or propyl.

12. The method of claim 11, wherein one or more of R₁, R₂, R₃ or R₄ is an ethyl group.

13. A method comprising:
placing a substrate within a reaction chamber, the substrate having a substrate surface;
heating the substrate to an intended temperature;
introducing a gaseous organometallic metal precursor into the reaction chamber, wherein at least a portion of the substrate surface is exposed to the gaseous organometallic metal precursor;
adsorbing the organometallic metal precursor onto the substrate surface, wherein the adsorbed organometallic metal precursor forms a continuous and conformal film on the substrate surface;
introducing gaseous organometallic metal reactant into the reaction chamber, wherein at least a portion of the continuous and conformal film on the substrate surface is exposed to the gaseous organometallic metal reactant; and
reacting the organometallic metal precursor with the organometallic metal reactant at the intended temperature to deposit a metal layer on the substrate surface.

14. The method of claim 13, which further comprises heating a liquid organometallic metal precursor to generate the gaseous organometallic metal precursor.

15. The method of claim 13, wherein the gaseous organometallic metal precursor is introduced into the reaction chamber through an ALD injector, which directs the gaseous organometallic metal precursor towards at least a portion of the substrate surface.

16. The method of claim 13, which further comprises forming a barrier layer on the substrate surface before introducing the gaseous organometallic metal precursor into the reaction chamber.

17. The method of claim 13, which further comprises repeating a cycle of introducing the organometallic metal precursor to expose the substrate surface and introducing the organometallic metal reactant to form additional metal layers on previously deposited metal layers.

18. The method of claim 17, wherein the deposited metal layer is in the range of about 0.5 Å to about 1000 Å, and has a purity of equal to or greater than 99.5%.

19. A method comprising:
placing a substrate having a substrate surface within a reaction chamber;
heating the substrate to a temperature in the range of about 75° C. to about 99° C.;
introducing gaseous Cu(DMAP)₂ into the reaction chamber;
adsorbing the Cu(DMAP)₂ onto the substrate surface, wherein the adsorbed Cu(DMAP)₂ forms a continuous and conformal Cu(DMAP)₂ film on the substrate surface;
introducing gaseous trimethyl aluminum or triethyl aluminum into the reaction chamber, wherein at least a portion of the continuous and conformal Cu(DMAP)₂ film on the substrate surface is exposed to the gaseous trimethyl aluminum or triethyl aluminum; and
reacting the Cu(DMAP)₂ with trimethyl aluminum or triethyl aluminum to deposit a Cu metal layer on the substrate surface, wherein the Cu metal layer has a thickness in the range of about 5 Å to about 1,000 Å, and a purity of greater than 99.5%.

20. The method of claim 19, further comprising electrochemically depositing Cu on the Cu metal layer.
